(19) United States
(12) Patent Application Publication
(10) Pub. No.: US 2019/0017826 A1
(43) Pub. Date: Jan. 17, 2019

(54) VECTOR MAGNETIC PRECISION GUIDANCE SYSTEM

(71) Applicant: LOCKHEED MARTIN CORPORATION, Bethesda, MD (US)

(72) Inventors: Stephen SEKELSKY, Bethesda, MD (US); Jay Thomas HANSEN, Bethesda, MD (US)

(73) Assignee: LOCKHEED MARTIN CORPORATION, Bethesda, MD (US)

(21) Appl. No.: 16/032,042

(22) Filed: Jul. 10, 2018

Related U.S. Application Data
(60) Provisional application No. 62/531,341, filed on Jul. 11, 2017.

(51) Int. Cl. G01C 21/04; G01R 33/032

(52) U.S. Cl. CPC G01C 21/04; G01R 33/032

(57) ABSTRACT

Some precision guidance systems and methods for detecting the position and orientation of one or more magnetic sources are disclosed. The precision guidance system can include a magneto-optical defect center sensor and a controller. The controller can be configured to detect one or more axial components of a magnetic source. Each of the one or more axial components can have a unique, predetermined magnetic signature. The controller can determine a position and orientation of the magnetic source based on the one or more axial components and output the determined position and orientation of the magnetic source to a guidance system.

### CROSS-REFERENCE TO RELATED APPLICATIONS

The application claims the benefit of, and priority to, U.S. Provisional Application No. 62/531,341 filed on Jul. 11, 2017, the contents of which are incorporated by reference herein.

### FIELD

The subject technology generally relates without limitation to magnetometers, and for example, to precision guidance systems using vector magnetometry.

### BACKGROUND

A number of industrial applications, as well as scientific areas such as physics and chemistry can benefit from magnetic detection and imaging with a device that has extraordinary sensitivity, ability to capture signals that fluctuate very rapidly (bandwidth) all with a substantive package that is extraordinarily small in size and efficient in power. Many advanced magnetic sensing systems can operate in restricted conditions, for example, high vacuum and/or cryogenic temperatures, which can make them inapplicable for sensing applications that require ambient or other conditions. Furthermore, small size, weight and power (SWAP) magnetic sensors of moderate sensitivity, vector accuracy, and bandwidth are valuable in many applications.

### SUMMARY

Some embodiments provide a precision guidance system that utilizes magneto-optical defect center sensors and magnetic sources having known unique magnetic signatures for corresponding X, Y, and Z axial components. The magneto-optical defect center sensors can simultaneously measure the magnetic fields of each of the magnetic sources and a controller can determine the position and orientation of each magnetic source based on X, Y, and Z axial components of each magnetic source. The precision guidance system can output the position and orientation as a vector to be utilized by an aircraft guidance system, space craft guidance system, ground-based guidance system, sea-based guidance system, or an under-sea-based guidance system.

Some embodiments may include a system that includes a magneto-optical defect center sensor and a controller. The controller can be configured to detect one or more axial components of a magnetic source, where each of the one or more axial components has a unique, predetermined magnetic signature. The controller can determine a position and orientation of the magnetic source based on the one or more axial components and output the determined position and orientation of the magnetic source to a guidance system or display.

In some implementations, the magneto-optical defect center sensor can be a diamond nitrogen vacancy sensor. In some implementations, the unique, predetermined magnetic signature can be a frequency modulation. In some implementations, the unique, predetermined magnetic signature can be a pulse width modulation. In some implementations, the guidance system can include a display to display the position and orientation of the magnetic source. In some implementations, the guidance system can be an auto-pilot system. In some implementations, the guidance system can be a ground-based guidance system of a vehicle. In some implementations, the guidance system can be a sea-based guidance system of a sea vessel or an under-sea-based guidance system of a submersible vessel.

Other embodiments relate to a system that includes two or more magneto-optical defect center sensors and a controller. The controller can be configured to detect, for each of the two or more magneto-optical defect center sensors, an X, Y, and Z axial component of two or more magnetic sources, where each of the X, Y, and Z axial components have a unique, predetermined magnetic signature. The controller can determine a position and orientation of each of the two or more magnetic sources based on the corresponding X, Y, and Z axial components and output the determined position and orientation of the two or more magnetic sources to a guidance system or display.

In some implementations, the magneto-optical defect center sensor can be a diamond nitrogen vacancy sensor. In some implementations, the unique, predetermined magnetic signature can be a frequency modulation. In some implementations, the unique, predetermined magnetic signature can be a pulse width modulation. In some implementations, the controller can include a subsystem for a multi-channel magnetic receiver, a filter for filtering corresponding X, Y, and Z axis components of each of the two or more magnetic sources, and a multi-lateration position and orientation determining subsystem. In some implementations, the two or more magnetic sources each comprise a rotating magnet. In some implementations, the two or more magnetic sources each comprise a magnetic coil.

Yet other embodiments relate to a method for determining a position and orientation of one or more magnetic sources utilizing one or more magneto-optical defect center sensors and a controller. The method can include accessing a baseline magnetic field measurement, detecting a X, Y, and Z axial component for each of the one or more magnetic sources based on a known magnetic signature for each of the X, Y, and Z axial components and the baseline magnetic field measurement, determining a position and orientation of each of the one or more magnetic sources based on the detected X, Y, and Z axial components, and outputting the determined position and orientation of the one or more magnetic sources.

In some implementations, the unique, predetermined magnetic signature can be a frequency modulation. In some implementations, the unique, predetermined magnetic signature can be a pulse width modulation. In some implementations, the one or more magneto-optical defect center sensors can be one or more diamond nitrogen vacancy sensors. In some implementations, the determined position and orientation of the one or more magnetic sources can be outputted to a guidance system of a vehicle.

In a further embodiment, a precision guidance system can include means for generating one or more magnetic fields for a magnetic source and means for determining a position and orientation of the magnetic source using a magneto-optical defect center sensor.

### BRIEF DESCRIPTION OF THE DRAWINGS

The details of one or more implementations are set forth in the accompanying drawings and the description below. Other features, aspects, and advantages of the disclosure will become apparent from the description, the drawings, and the claims, in which:

FIG. 1 illustrates an orientation of an NV center in a diamond lattice;

FIG. 2 illustrates an energy level diagram showing energy levels of spin states for the NV center;

FIG. 3 illustrates a schematic diagram of a NV center magnetic sensor system;

FIG. 4 is a graph illustrating the fluorescence as a function of an applied RF frequency of an NV center along a given direction for a zero magnetic field, and also for a non-zero magnetic field having a component along the NV axis;

FIG. 5 is a graph illustrating the fluorescence as a function of an applied RF frequency for four different NV center orientations for a non-zero magnetic field;

FIG. 6 is a graphical diagram illustrating a Ramsey pulse sequence;

FIG. 7 is a schematic diagram illustrating a precision guidance system including magneto-optical defect center sensors;

FIG. 8 illustrates a process diagram for detecting a position and orientation of a magnetic source; and

FIG. 9 is a block diagram illustrating a general architecture for a computer system that may be employed to implement various elements of the systems and methods described and illustrated herein.

It will be recognized that some or all of the figures are schematic representations for purposes of illustration. The figures are provided for the purpose of illustrating one or more embodiments with the explicit understanding that they will not be used to limit the scope or the meaning of the claims.

### DETAILED DESCRIPTION

Following below are more detailed descriptions of various concepts related to, and implementations of, methods, apparatuses, and systems for a precision guidance system using vector magnetometry.

Some implementations of guidance systems utilize radio frequency identifiers (RFID) or RF beacons as indicators to be detected for guidance systems. However, other RF sources, such as passive or active RF sources, may interfere with the detection of such RF beacons. Moreover, weather conditions, such as fog or rain, may also obscure the RF beacons from detection. In contrast to such RF guidance systems, magneto-optical defect center sensors utilizing encoded vector magnetic sources are not impacted by other RF sources and/or the presence of fog or rain weather conditions. Moreover, other magnetic sources do not substantially impact the detection of encoded vector magnetic sources as the external magnetic source would simply register as background magnetic noise.

Atomic-sized magneto-optical defect centers, such as nitrogen-vacancy (NV) centers in diamond lattices, have excellent sensitivity for magnetic field measurement and enable fabrication of small magnetic sensors. Magneto-optical defect center materials include but are not be limited to diamonds, Silicon Carbide (SiC), Phosphorous, and other materials with nitrogen, boron, carbon, silicon, or other defect centers. Magneto-optical defect center sensors, such as a diamond nitrogen vacancy (DNV) sensor, can be maintained in room temperature and atmospheric pressure and can be even used in liquid environments. For a DNV sensor, a green optical source (e.g., a micro-LED) can optically excite NV centers of the DNV sensor and cause emission of fluorescence radiation (e.g., red light) under off-resonant optical excitation. A magnetic field generated, for example, by a microwave coil can probe triplet spin states (e.g., with mₛ=−1, 0, +1) of the NV centers to split in relation to an external magnetic field projected along the NV axis, resulting in two spin resonance frequencies. The difference between the two spin resonance frequencies can correlate to a measure of the strength of the external magnetic field. A photo detector can measure the fluorescence (red light) emitted by the optically excited NV centers.

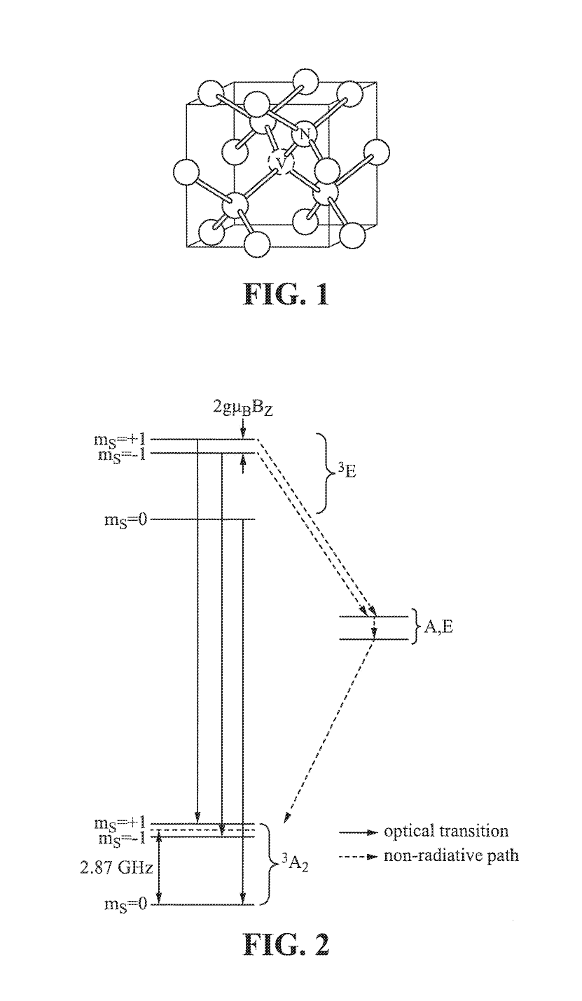

Nitrogen-vacancy centers (NV centers) are defects in a diamond's crystal structure, which can purposefully be manufactured in synthetic diamonds as shown in FIG. 1. In general, when excited by green light and microwave radiation, the NV centers cause the diamond to generate a red light. When excited with green light, the NV defect centers generate red light fluorescence. After sufficient time (e.g., in the order of nanoseconds to microseconds) the fluorescence counts stabilize. When microwave radiation is added, the NV electron spin states are changed, and this results in a change in intensity of the red fluorescence. The changes in fluorescence may be recorded as a measure of electron spin resonance. By measuring the changes, the NV centers may be used to accurately detect the magnetic field strength.

The NV center may exist in a neutral charge state or a negative charge state. Conventionally, the neutral charge state uses the nomenclature NV⁰, while the negative charge state uses the nomenclature NV, which is adopted in this description.

The NV center may have a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry and, as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by a zero field splitting of approximately 2.87 GHz for a zero external magnetic field.

Introducing the external magnetic field with the component along the NV axis lifts the degeneracy of the mₛ=±1 energy levels, splitting the energy levels mₛ=±1 by an amount 2gμ_{B}B_{z}, where g is the Lande g-factor, μ_{B} is the Bohr magneton, and B_{z} is the component of the external magnetic field along the NV axis. This relationship is correct to a first order and inclusion of higher order corrections is a straightforward matter.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

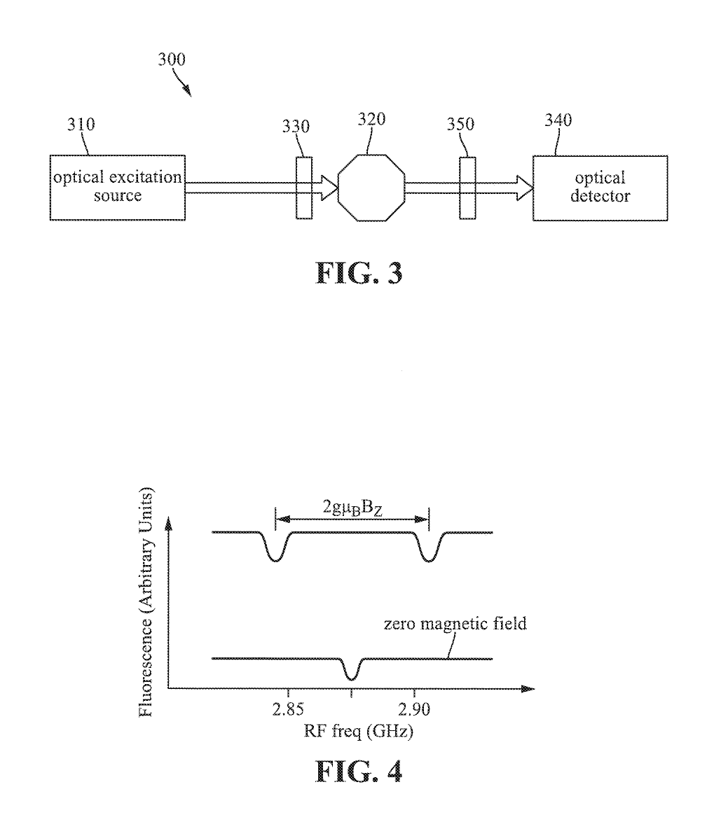

FIG. 3 is a schematic diagram illustrating a magneto-optical defect center sensor system 300 that uses fluorescence intensity to distinguish the mₛ=±1 states, and to measure the magnetic field based on the energy difference between the mₛ=+1 state and the mₛ=−1 state, as manifested by the RF frequencies corresponding to each state. The system 300 includes an optical excitation source 310, which directs optical excitation to a magneto-optical defect center material 320 with magneto-optical defect centers. The system further includes an RF excitation source 330, which provides RF radiation to the magneto-optical defect center material 320. Light from the magneto-optical defect center material may be directed through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance and a subsequent decrease in fluorescence intensity occurs between the mₛ=0 spin state and the mₛ=−1 spin state of the ground state when the photon energy of the RF radiation emitted by the RF excitation source is the difference in energies of the mₛ=0 spin state and the mₛ=−1 spin state.

The optical excitation source 310 may be a laser or a light emitting diode, for example, which emits light in the green (light having a wavelength such that the color is green), for example. The optical excitation source 310 induces fluorescence in the red, which corresponds to an electronic transition from the excited state to the ground state. Light from the magneto-optical defect center material 320 is directed through the optical filter 350 to filter out light in the excitation band (in the green, for example), and to pass light in the red fluorescence band, which in turn is detected by the detector 340. The optical excitation light source 310, in addition to exciting fluorescence in the magneto-optical defect center material 320, also serves to reset the population of the mₛ=0 spin state of the ground state ³A₂ to a maximum polarization, or other desired polarization.

For continuous wave excitation, the optical excitation source 310 continuously pumps the magneto-optical defect centers, and the RF excitation source 330 sweeps across a frequency range, which includes the zero splitting (when the mₛ=±1 spin states have the same energy) photon energy of approximately 2.87 GHz for NV centers. The fluorescence for an RF sweep corresponding to a magneto-optical defect center material 320 with magneto-optical defect centers aligned along a single direction is shown in FIG. 4 for different magnetic field components B_{z} along the magneto-optical defect axis, where the energy splitting between the mₛ=−1 spin state and the mₛ=+1 spin state increases with B_{z}. Thus, the component B_{z} may be determined. Optical excitation schemes other than continuous wave excitation are contemplated, such as excitation schemes involving pulsed optical excitation, and pulsed RF excitation. Examples of pulsed excitation schemes include Ramsey pulse sequence (described in more detail below), spin echo pulse sequence, etc.

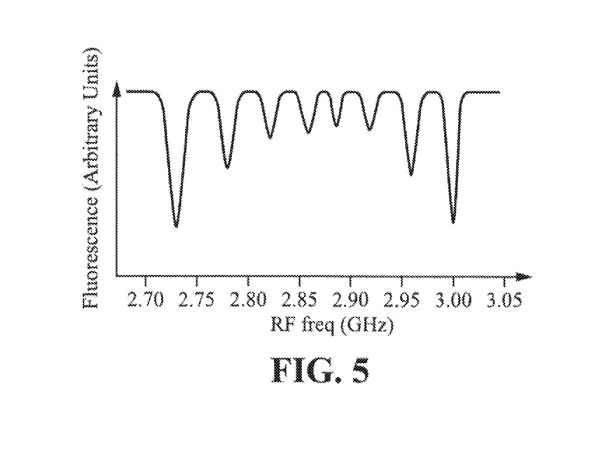

In general, the magneto-optical defect center material 320 will have magneto-optical defect centers aligned along directions of four different orientation classes. FIG. 5 illustrates fluorescence as a function of RF frequency for the case where the magneto-optical defect center material 320 has magneto-optical defect centers aligned along directions of four different orientation classes. In this case, the component B_{z} along each of the different orientations may be determined. These results, along with the known orientation of crystallographic planes of a magneto-optical defect material lattice, allow not only the magnitude of the external magnetic field to be determined, but also the direction of the magnetic field.

While FIG. 3 illustrates a magneto-optical defect center sensor system 300 with a magneto-optical defect center material 320 having a plurality of magneto-optical defect centers, such as a DNV material with NV centers. In general, the magnetic sensor system may instead employ a different magneto-optical defect center material with a plurality of magneto-optical defect centers. Magneto-optical defect center materials include but are not be limited to diamonds, Silicon Carbide (SiC), Phosphorous, and other materials with nitrogen, boron, carbon, silicon, or other defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with magneto-optical defect center material.

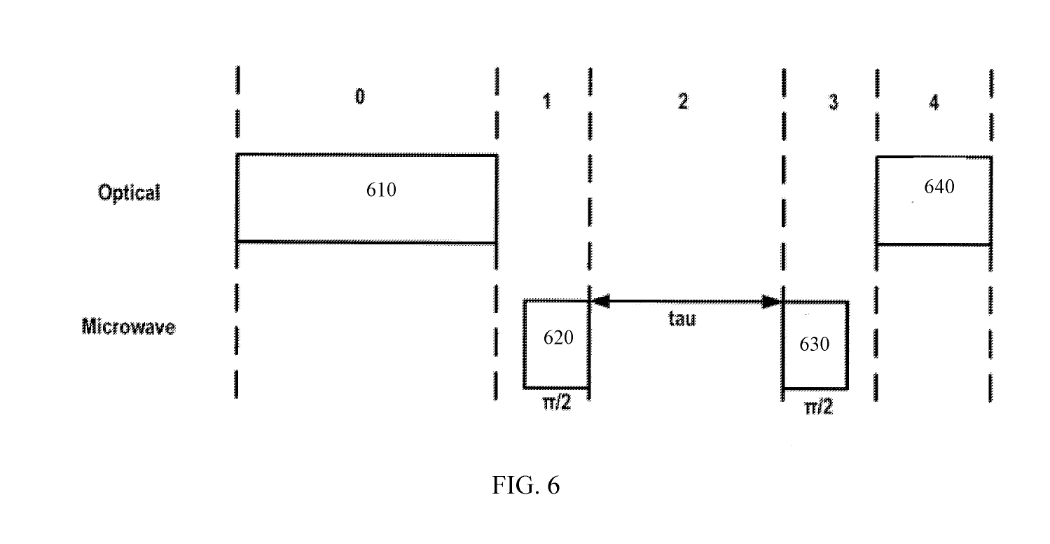

A Ramsey pulse sequence is a pulsed RF laser scheme that is believed to measure the free precession of the magnetic moment in the magneto-optical defect center material 320 with magneto-optical defect centers, and is a technique that quantum mechanically prepares and samples the electron spin state. FIG. 6 is an example of a schematic diagram illustrating the Ramsey pulse sequence. As shown in FIG. 6, a Ramsey pulse sequence includes optical excitation pulses and RF excitation pulses over a five-step period. In a first step, during a period 0, a first optical excitation pulse 610 is applied to the system to optically pump electrons into the ground state (i.e., mₛ=0 spin state). This is followed by a first RF excitation pulse 620 (in the form of, for example, a microwave (MW) π/2 pulse) during a period 1. The first RF excitation pulse 620 sets the system into superposition of the mₛ=0 and mₛ=+1 spin states (or, alternatively, the mₛ=0 and mₛ=−1 spin states, depending on the choice of resonance location). During a period 2, the system is allowed to freely precess (and dephase) over a time period referred to as tau (τ). During this free precession time period, the system measures the local magnetic field and serves as a coherent integration. Next, a second RF excitation pulse 630 (in the form of, for example, a MW π/2 pulse) is applied during a period 3 to project the system back to the mₛ=0 and mₛ=+1 basis. Finally, during a period 4, a second optical pulse 640 is applied to optically sample the system and a measurement basis is obtained by detecting the fluorescence intensity of the system. The RF excitation pulses applied are provided at a given RF frequency in relation to the Lorentzians such as referenced in connection with FIG. 5.

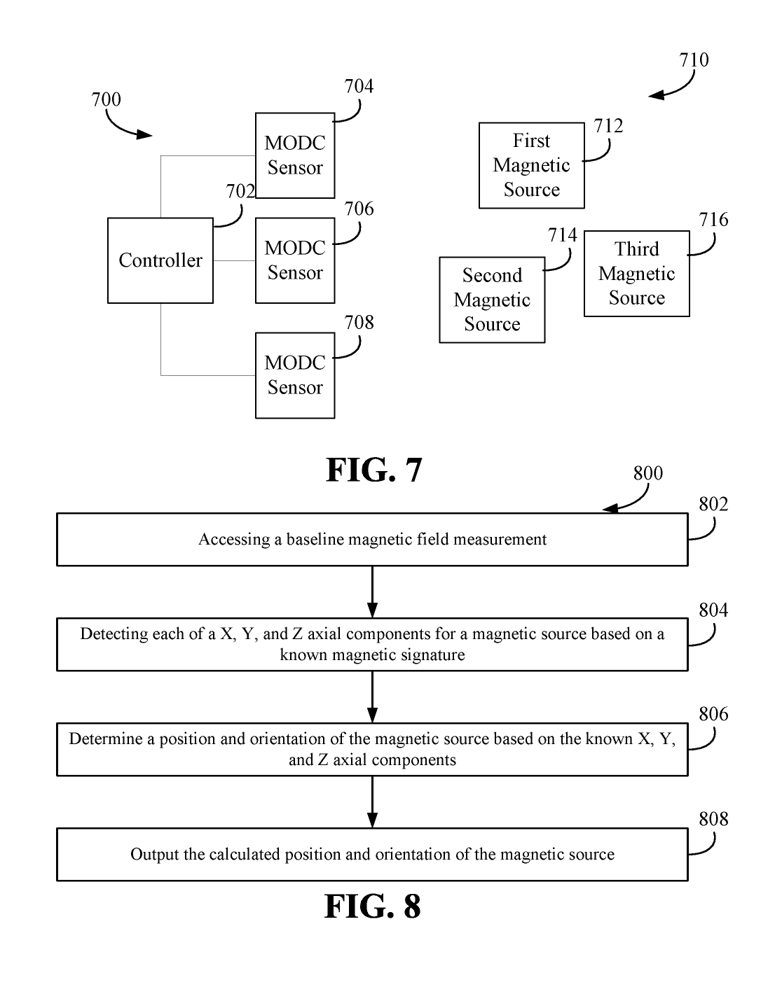

Referring to FIG. 7, high sensitivity, high bandwidth, full vector magnetometry sensing may be provided by a system 700 having a set of magneto-optical defect center sensors 704, 706, 708 to estimate the location of one or more magnetic sources 712, 714, 716 with known modulated X, Y, and Z axial components. In some implementations, the one or more magnetic sources 712, 714, 716 can be communicatively coupled to a multi-channel frequency modulation controller to control the known modulated X, Y, and Z axial components for each of the one or more magnetic sources 712, 714, 716. A magneto-optical defect center (MODC) sensor 704, 706, 708 is capable of resolving a vector of one or more magnetic sources 712, 714, 716. Each of the one or more magnetic sources 712, 714, 716 have orthogonal modulated X, Y, and Z axis components to generate a magnetic field for the corresponding axis. In some implementations, the modulated X, Y, and Z axis components can be rotating magnets. In other implementations, the modulated X, Y, and Z axis components can be electromagnetic coils. In still other implementations, the modulated X, Y, and Z axis components can be other modulated magnetic generation components.

The modulated X, Y, and Z axis components are magnetically distinct from each other such that the magneto-optical defect center sensor 704, 706, 708 can distinguish between each of the modulated X, Y, and Z axis components of a corresponding magnetic source 712, 714, 716. In some implementations, the modulated X, Y, and Z axis components have different frequencies for each of the modulated axial components. In other implementations, the modulated X, Y, and Z axis components may have different pulse width modulation signals or other unique magnetic signatures (i.e., non-naturally occurring magnetic signatures). The orthogonal modulated X, Y, and Z axis components are predetermined such that a controller 702, as described in greater detail below, can distinguish and identify a corresponding magnetic signature of each X, Y, and Z component of the corresponding magnetic source 712, 714, 716.

In implementations with multiple magnetic sources, each X, Y, and Z axial component of each of the one or more magnetic sources 712, 714, 716 may be distinguishable based on unique magnetic signatures such as frequency, pulse width modulation, or other characteristics as discussed above. Thus, a single magneto-optical defect center sensor 704, 706, 708 can simultaneously measure an experienced magnetic field and the controller 702, described in greater detail below, can extract a position and orientation for each of the one or more magnetic sources 712, 714, 716 based on the identifiable X, Y, and Z axial components of each magnetic source 712, 714, 716.

In some implementations, two or more magneto-optical defect center sensors 704, 706, 708 can be implemented for multi-lateration of multiple magnetic sources 712, 714, 716, such as one, two, or three or more magnetic sources. In still further implementations, three or more magneto-optical defect center sensors 704, 706, 708 can be implemented for multi-lateration of multiple magnetic sources 712, 714, 716, such as one, two, or three or more magnetic sources. Additional magneto-optical defect center sensors 704, 706, 708 can improve precision by providing additional data for multi-lateration of the multiple magnetic sources 712, 714, 716 when the position and orientation of each of the magneto-optical defect center sensors 704, 706, 708 is known. Where more than one magneto-optical defect center sensor 704, 706, 708 is utilized, such as shown in FIG. 7, the controller 702, having the known characteristics of the modulated X, Y, and Z axis components for each vector magnetic source 712, 714, 716, can further determine the position and orientation of each magnetic source 712, 714, 716 based on the corresponding identified X, Y, and Z axis components relative to known positions of each of the magneto-optical defect center sensors 704, 706, 708.

To determine the position and orientation of the one or more magnetic sources 712, 714, 716, the controller 702 receives magnetic measurement inputs from one or more magneto-optical defect center sensors 704, 706, 708 and computes a location and orientation of each magnetic source 712, 714, 716 based on the magnetic fields as measured by each of the magneto-optical defect center sensors 712, 714, 716. In some implementations, the controller 702 can include a subsystem for a multi-channel magnetic receiver, a filter to filter the X, Y, and Z axis components of each of the one or more magnetic sources 712, 714, 716, and a multi-lateration position and orientation determining subsystem.

In some implementations, the one or more magnetic sources 712, 714, 716 could be deployable units, such as battery-operated beacon with rotating magnets for the modulated X, Y, and Z axial components. The deployable units can be manually placed, such as beacons on a tripod or stake to be placed on a surface. In some implementations, the deployable units may include air cushioning, such as an air bag, such that the unit can be dropped from an altitude above a surface. In other implementations, the deployable units may include a parachute, wings, or other aerodynamic components to permit the deployable units to be deployed from an altitude above a surface.

In other implementations, the one or more magnetic sources 712, 714, 716 can be fixed to a surface, such as a deck of a ship, an exterior of a spacecraft, an aircraft runway, a vehicle loading bay, a buoy, a garage, a roadway, a building, etc.

The one or more magneto-optical defect center sensors 704, 706, 708 are fixed to a vehicle or object of interest for which the precision guidance system is to be implemented. In some implementations, the vehicle is a rotary wing aircraft, a fixed wing aircraft, a ship, a spacecraft, a motor vehicle, a robotic vehicle, a projectile, etc.

In contrast to RFID guidance systems, the instantaneous vector detection by the magneto-optical defect center sensors provide high bandwidth to detect the position and orientation of each of the one or more magnetic sources simultaneously by each magneto-optical defect center sensor. Such magneto-optical defect center sensors provide a higher sensitivity and vector detection in a single compact sensor.

The controller 702, in addition to controlling the one or more magneto-optical defect center sensors 704, 706, 708 and receiving data from the one or more magneto-optical defect center sensors 704, 706, 708, may perform data processing on the data output from each of the one or more magneto-optical defect center sensors 704, 706, 708. In this regard, the controller 702 may include a subcontroller to control and receive data from the one or more magneto-optical defect center sensors 704, 706, 708, and one or more further subcontrollers to perform data processing on the data. Each of the one or more magneto-optical defect center sensors 704, 706, 708 takes multiple measurements over time and/or can take a single measurement during the same time window. In some implementations, the controller 702 may have the set of one or more magneto-optical defect center sensors 704, 706, 708 take an initial measurement with no magnetic sources 712, 714, 716 present to provide a base measurement such that a variation in the measurement from the one or more magneto-optical defect center sensors 704, 706, 708 can be detected when the one or more magnetic sources 712, 714, 716 is present. That is, the controller 702 may store a base magnetic field measurement to compare to subsequent measurements from the one or more magneto-optical defect center sensors 704, 706, 708. Subsequent measurements can be compared to the base measurement to detect the presence of one or more magnetic sources 712, 714, 716.

In some implementations, the unique magnetic signature for the known modulated X, Y, and Z axial components of each of the one or more magnetic sources 712, 714, 716 can be selected to be distinguishable from the base magnetic field measurement. Thus, when a subsequent measurement is taken by the one or more magneto-optical defect center sensors 704, 706, 708, the unique magnetic signature, such as the frequency modulation or pulse width modulation, changes the magnetic signal of each of the modulated X, Y, and Z axial components differently such that each modulated axial component can be distinguished in the measured magnetic field and then utilized to determine the position and orientation of the corresponding magnetic source 712, 714, 716 relative to the magneto-optical defect center sensor 704, 706, 708.

In some implementations, the one or more magneto-optical defect center sensors 704, 706, 708 each take a measurement of a magnetic field once per second or at any other sampling rate. The controller 702 can receive vector magnetic measurements taken by the one or more magneto-optical defect center sensors 704, 706, 708. In some implementations, the measurements are received simultaneously from the one or more magneto-optical defect center sensors 704, 706, 708. The controller 702 receives each of the measurements and stores them as sets of measurements to be used to determine the position of the one or more magnetic sources 712, 714, 716 as described below.

Referring to FIG. 8, the controller, such as controller 702, implements the process 800 for determining the location of one or more magnetic sources, such as one or more magnetic sources 712, 714, 716, based on the known modulated X, Y, and Z axial components of each of the one or more magnetic sources. The process 800 includes accessing a baseline magnetic field measurement (block 802). Accessing the baseline magnetic field measurement may include directly accessing magnetic field measurement data from a magneto-optical defect center sensor or retrieving magnetic field measurement data from a data storage, such as a memory or storage device. The baseline magnetic field measurement can be a magnetic field measurement detected by the magneto-optical defect center sensor that is indicative of an ambient magnetic field without the magnetic fields generated by the one or more magnetic sources.

The process 800 further includes detecting each of the X, Y, and Z axial components for a magnetic source based on the known magnetic signature (block 804).

Once the axial components for a corresponding magnetic source are known, the controller determines a position and orientation of the magnetic source based on the known X, Y, and Z axial components (block 806). Based on the orthogonal X, Y, and Z axial components, the orientation of the magnetic source relative to the magneto-optical defect center sensor may be determined. In addition, with the known orientation and expected strength of each of the orthogonal X, Y, and Z axial components, the controller determines the position of the magnetic source.

In instances where there are multiple magnetic sources, the process 800 may repeat for each magnetic source and/or may occur in parallel for each magnetic source. In addition, for multiple magneto-optical defect center sensors, the process 800 may further include averaging the calculated orientations and/or positions as measure by each magneto-optical defect center sensor to determine the position of each magnetic source.

The process 800 can further include outputting the calculated position and orientation of the magnetic source (block 808). As noted above, the one or more magnetic sources can be fixed to a surface, such as a deck of a ship, an exterior of a spacecraft, an aircraft runway, a vehicle loading bay, a buoy, a garage, a roadway, a building, etc. The one or more magneto-optical defect center sensors can be fixed to a vehicle or object of interest for which the precision guidance system is to be implemented. In some implementations, the vehicle may be a rotary wing aircraft, a fixed wing aircraft, a ship, a spacecraft, a motor vehicle, a robotic vehicle, a projectile, etc. The outputted position and orientation of the one or more magnetic sources can be output to a display system, such as a heads-up display, a screen display, or another display.

In other implementations, the outputted position and orientation can be output to another system. For instance, the position and orientation can be output to an auto-pilot system. The auto-pilot system can be used to control an orientation and/or position of an aircraft, such as a rotary wing or fixed wing aircraft, or a spacecraft relative to the one or more magnetic sources. The magnetic sources may be positioned relative to a runway for guidance of a fixed wing aircraft to land relative to a landing strip. The magnetic sources may be positioned relative to a landing surface, such as a surface of a ship or an ad hoc landing zone, for guidance of a rotary wing aircraft to land. The magnetic sources may be positioned relative to a landing or docking surface for guidance of a spacecraft to land relative to the landing surface, such as a surface of a ship, a launch pad, etc., or for docking guidance relative to another spacecraft or other object with which the spacecraft is to dock.

In other implementations, the position and orientation can be output to a ground-based guidance system, such as a vehicle parking or control system. The ground-based guidance system can receive the orientation and/or position of the one or more magnetic sources and control a position of the vehicle, such as guiding an automatic parking system, controlling a truck to dock with a loading bay, and/or control a robotic vehicle, such as a robotic vehicle in a manufacturing setting or other settings. The magnetic sources can be positioned within a parking structure, garage, or other parking area for the ground-based guidance system to park a vehicle. The magnetic sources can be positioned on a loading bay for the ground-based guidance system to guide a truck to align a trailer or other storage unit with the loading bay. The magnetic sources can be positioned within a guidance areas in a warehouse or manufacturing facility for the ground-based guidance system to guide a robotic vehicle within the warehouse of the manufacturing facility.

In still further implementations, the position and orientation can be output to a sea-based guidance system, such as a ship guidance system, or an under-sea-based guidance system, such as for a submersible vehicle. The sea-based or under-sea-based guidance system can receive the orientation and/or position of the one or more magnetic sources and control a position of a ship relative to the magnetic sources. The magnetic sources can be positioned on one or more buoys to guide a ship or a submersible through a harbor, channel, along sea floor features, or other region.

In still further implementations, the magnetic sources can be deployable magnetic sources, such as tripod mounted magnetic sources to be deployed in a field or other zone of interest. In some implementations, the magnetic sources may be dropped in a field or other zone of interest. In some implementations, the magnetic sources may be parachuted into a field or other zone of interest. In some implementations, the magnetic sources may be launched as a payload into a field or other zone of interest. In some implementations, the magnetic sources may be dropped from a ship or submersible in a field or other zone of interest, either to float above water or to be positioned along the sea floor. In some implementations, the magnetic sources may be parachuted into a field or other zone of interest, either to float above water or to be positioned along the sea floor. In some implementations, the magnetic sources may be launched as a payload into a field or other zone of interest, either to float above water or to be positioned along the sea floor.

In one example, three magnetic sources may be used with three fixed magneto-optical defect center sensors. Each magneto-optical defect center sensor simultaneously measures each of the X, Y, and Z components of each of the three magnetic sources in a nine channel implementation. The controller then determines the position and orientation of each of the magnetic sources for each of the magneto-optical defect center sensors and the three positions and orientations of each magnetic source for each magneto-optical defect center sensor can be used to estimate the true position of the three magnetic sources and a plane of the magnetic sources relative to the known plane of the magneto-optical defect center sensors.

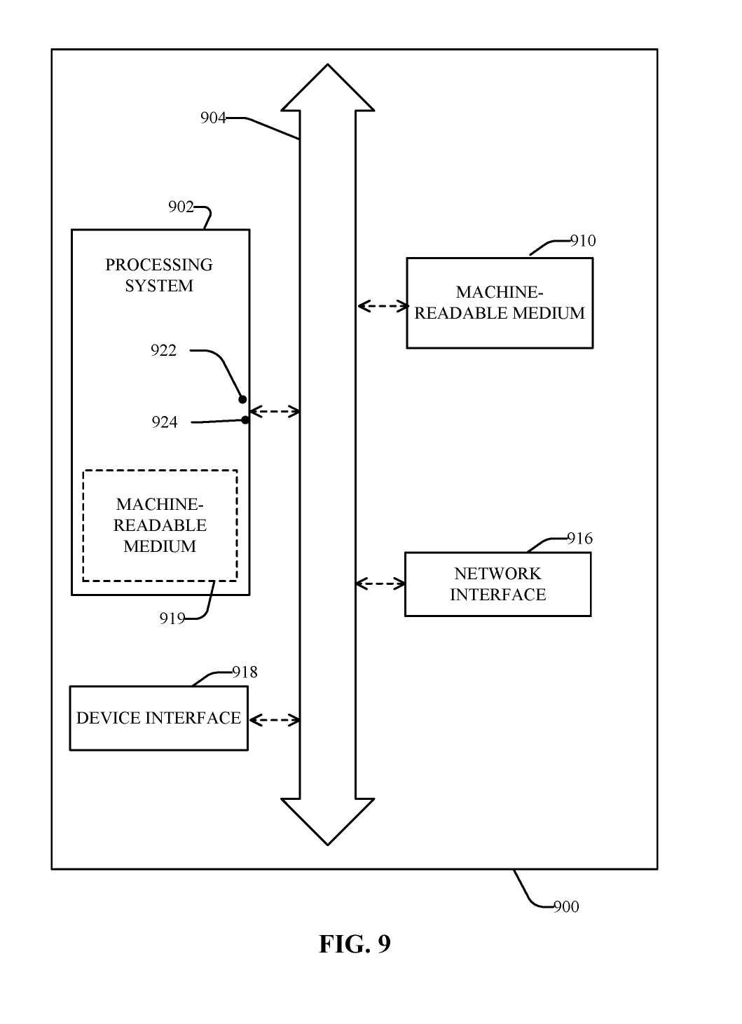

FIG. 9 is a diagram illustrating an example of a system 900 for implementing some aspects such as the controller. The system 900 includes a processing system 902, which may include one or more processors or one or more processing systems. A processor may be one or more processors. The processing system 902 may include a general-purpose processor or a specific-purpose processor for executing instructions and may further include a machine-readable medium 919, such as a volatile or non-volatile memory, for storing data and/or instructions for software programs. The instructions, which may be stored in a machine-readable medium 910 and/or 919, may be executed by the processing system 902 to control and manage access to the various networks, as well as provide other communication and processing functions. The instructions may also include instructions executed by the processing system 902 for various user interface devices, such as a display 912 and a keypad 914. The processing system 902 may include an input port 922 and an output port 924. Each of the input port 922 and the output port 924 may include one or more ports. The input port 922 and the output port 924 may be the same port (e.g., a bi-directional port) or may be different ports.

The processing system 902 may be implemented using software, hardware, or a combination of both. By way of example, the processing system 902 may be implemented with one or more processors. A processor may be a general-purpose microprocessor, a microcontroller, a Digital Signal Processor (DSP), an Application Specific Integrated Circuit (ASIC), a Field Programmable Gate Array (FPGA), a Programmable Logic Device (PLD), a controller, a state machine, gated logic, discrete hardware components, or any other suitable device that can perform calculations or other manipulations of information.

A machine-readable medium may be one or more machine-readable media, including no-transitory or tangible machine-readable media. Software shall be construed broadly to mean instructions, data, or any combination thereof, whether referred to as software, firmware, middleware, microcode, hardware description language, or otherwise. Instructions may include code (e.g., in source code format, binary code format, executable code format, or any other suitable format of code).

Machine-readable media (e.g., 919) may include storage integrated into a processing system such as might be the case with an ASIC. Machine-readable media (e.g., 910) may also include storage external to a processing system, such as a Random Access Memory (RAM), a flash memory, a Read Only Memory (ROM), a Programmable Read-Only Memory (PROM), an Erasable PROM (EPROM), registers, a hard disk, a removable disk, a CD-ROM, a DVD, or any other suitable storage device. Those skilled in the art will recognize how best to implement the described functionality for the processing system 902. According to one aspect of the disclosure, a machine-readable medium may be a computer-readable medium encoded or stored with instructions and may be a computing element, which defines structural and functional interrelationships between the instructions and the rest of the system, which permit the instructions' functionality to be realized. Instructions may be executable, for example, by the processing system 902 or one or more processors. Instructions can be, for example, a computer program including code for performing methods of some of the embodiments.

A network interface 916 may be any type of interface to a network (e.g., an Internet network interface), and may reside between any of the components shown in FIG. 9 and coupled to the processor via the bus 904.

A device interface 918 may be any type of interface to a device and may reside between any of the components shown in FIG. 9. A device interface 918 may, for example, be an interface to an external device (e.g., USB device) that plugs into a port (e.g., USB port) of the system 900.

One or more of the above-described features and applications may be implemented as software processes that are specified as a set of instructions recorded on a computer readable storage medium (alternatively referred to as computer-readable media, machine-readable media, or machine-readable storage media). When these instructions are executed by one or more processing unit(s) (e.g., one or more processors, cores of processors, or other processing units), they cause the processing unit(s) to perform the actions indicated in the instructions. In one or more implementations, the computer readable media does not include carrier waves and electronic signals passing wirelessly or over wired connections, or any other ephemeral signals. For example, the computer readable media may be entirely restricted to tangible, physical objects that store information in a form that may be readable by a computer. In one or more implementations, the computer readable media may be non-transitory computer readable media, computer readable storage media, or non-transitory computer readable storage media.

In one or more implementations, a computer program product (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one computer or on multiple computers that are located at one site or distributed across multiple sites and interconnected by a communication network.

While the above discussion primarily refers to microprocessor or multi-core processors that execute software, one or more implementations are performed by one or more integrated circuits, such as application specific integrated circuits (ASICs) or field programmable gate arrays (FPGAs). In one or more implementations, such integrated circuits execute instructions that are stored on the circuit itself.

In some aspects, some embodiments directed to precision guidance systems and anomaly detection using diamond nitrogen-vacancy (DNV). In some aspects, some embodiments may be used in various markets, including for example and without limitation, advanced sensors and magnetic guidance systems markets.

The description is provided to enable any person skilled in the art to practice the various embodiments described herein. While some embodiments have been particularly described with reference to the various figures and configurations, it should be understood that these are for illustration purposes only and should not be taken as limiting the scope of the subject technology.

There may be many other ways to implement. Various functions and elements described herein may be partitioned differently from those shown without departing from the scope of the subject technology. Various modifications to these embodiments may be readily apparent to those skilled in the art, and generic principles defined herein may be applied to other embodiments. Thus, many changes and modifications may be made by one having ordinary skill in the art, without departing from the scope of the subject technology.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various embodiments described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

What is claimed is:

1. A system comprising:
a magneto-optical defect center sensor; and
a controller, the controller configured to:
detect one or more axial components of a magnetic source, each of the one or more axial components having a unique, predetermined magnetic signature,
determine a position and orientation of the magnetic source based on the one or more axial components, and
output the determined position and orientation of the magnetic source to a guidance system or display.

2. The system of claim 1, wherein the magneto-optical defect center sensor is a diamond nitrogen vacancy sensor.

3. The system of claim 1, wherein the unique, predetermined magnetic signature is a frequency modulation.

4. The system of claim 1, wherein the unique, predetermined magnetic signature is a pulse width modulation.

5. The system of claim 1, wherein the guidance system comprises a display to display the position and orientation of the magnetic source.

6. The system of claim 1, wherein the guidance system comprises an auto-pilot system.

7. The system of claim 1, wherein the guidance system comprises a ground-based guidance system of a vehicle.

8. The system of claim 1, wherein the guidance system comprises a sea-based guidance system or an under-sea-based guidance system of a sea vessel.

9. A system comprising:
two or more magneto-optical defect center sensors; and
a controller, the controller configured to:
detect, for each of the two or more magneto-optical defect center sensors, an X, Y, and Z axial component of two or more magnetic sources, each of the X, Y, and Z axial components having a unique, predetermined magnetic signature,
determine a position and orientation of each of the two or more magnetic sources based on the corresponding X, Y, and Z axial components, and
output the determined position and orientation of the two or more magnetic sources to a guidance system or display.

10. The system of claim 9, wherein the two or more magneto-optical defect center sensors are diamond nitrogen vacancy sensors.

11. The system of claim 9, wherein the unique, predetermined magnetic signature is a frequency modulation.

12. The system of claim 9, wherein the unique, predetermined magnetic signature is a pulse width modulation.

13. The system of claim 9, wherein the controller comprises a subsystem for a multi-channel magnetic receiver, a filter for filtering corresponding X, Y, and Z axis components of each of the two or more magnetic sources, and a multi-lateration position and orientation determining subsystem.

14. The system of claim 9, wherein the two or more magnetic sources each comprise a rotating magnet.

15. The system of claim 9, wherein the two or more magnetic sources comprise a magnetic coil.

16. A method for determining a position and orientation of one or more magnetic sources utilizing one or more magneto-optical defect center sensors and a controller, the method comprising:
accessing a baseline magnetic field measurement;
detecting a X, Y, and Z axial component for each of the one or more magnetic sources based on a known magnetic signature for each of the X, Y, and Z axial components and the baseline magnetic field measurement;
determining a position and orientation of each of the one or more magnetic sources based on the detected X, Y, and Z axial components; and
outputting the determined position and orientation of the one or more magnetic sources.

17. The method of claim 16, wherein the unique, predetermined magnetic signature is a frequency modulation.

18. The method of claim 16, wherein the unique, predetermined magnetic signature is a pulse width modulation.

19. The method of claim 16, wherein the one or more magneto-optical defect center sensors are one or more diamond nitrogen vacancy sensors.

20. The method of claim 16, wherein the determined position and orientation of the one or more magnetic sources are outputted to a guidance system of a vehicle.

21. A precision guidance system comprising:
means for generating one or more magnetic fields for a magnetic source; and
means for determining a position and orientation of the magnetic source using a magneto-optical defect center sensor.
